(19) United States
(12) Patent Application Publication
(10) Pub. No.: US 2024/0404802 A1
(43) Pub. Date: Dec. 5, 2024

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventors: Atsushi Moriya, Toyama-shi (JP); Toshiyuki Kikuchi, Toyama-shi (JP); Naofumi Ohashi, Toyama-shi (JP)

(73) Assignee: Kokusai Electric Corporation, Tokyo (JP)

(21) Appl. No.: 18/621,292

(22) Filed: Mar. 29, 2024

(30) Foreign Application Priority Data
May 31, 2023 (JP) 2023-090226

(51) Int. Cl. H01J 37/32; C23C 16/458; C23C 16/56; H01L 21/02

(52) U.S. Cl. CPC H01J 37/32788; C23C 16/4586; C23C 16/56; H01J 37/32357; H01J 37/32449; H01J 37/32724; H01L 21/02274; H01J 2237/332; H01L 21/02126; H01L 21/02216

(57) ABSTRACT

There is provided a technique that includes: (a) mounting a substrate on a mounting stage in which at least a part of a surface is constituted by a first member; (b) forming films by supplying a first gas, the films including a first film formed on a surface of the substrate and a second film having a portion continuous with the first film and formed on a surface of the first member; and (c) generating stress attributable to a difference in thermal deformation amount between the first member and the substrate, inside the second film, and making at least a part of the second film discontinuous.

### CROSS-REFERENCE TO RELATED APPLICATION

This application is based upon and claims the benefit of priority from Japanese Patent Application No. 2023-090226, filed on May 31, 2023, the entire contents of which are incorporated herein by reference.

### FIELD

The present disclosure relates to a method of processing a substrate, a method of manufacturing a semiconductor device, a substrate processing apparatus, and a recording medium.

### DESCRIPTION OF THE RELATED ART

As one step in a substrate processing step, a process of forming a film on a surface of a substrate mounted on a mounting stage is sometimes performed.

### SUMMARY

In such a substrate process, when a film is formed so as to be continuous between a surface of the substrate and a surface of the mounting stage, failure in transferring the substrate or damage to the substrate occurs in some cases.

The present disclosure provides a technique capable of suppressing failure in transferring a substrate and damage to a substrate.

According to one aspect of the present disclosure,
a technique is provided, the technique including:
(a) mounting a substrate on a mounting stage in which at least a part of a surface is constituted by a first member;
(b) forming films by supplying a first gas, the films including a first film formed on a surface of the substrate and a second film having a portion continuous with the first film and formed on a surface of the first member; and
(c) generating stress attributable to a difference in thermal deformation amount between the first member and the substrate, inside the second film, and making at least a part of the second film discontinuous.

### BRIEF DESCRIPTION OF THE DRAWINGS

FIG. 1 is a longitudinal cross-sectional view of a substrate processing apparatus used in one or more embodiments of the present disclosure.

FIG. 2A is an enlarged cross-sectional view in which a mounting stage of the substrate processing apparatus illustrated in FIG. 1 is enlarged.

FIG. 2B is a plan view of the mounting stage illustrated in FIG. 2A.

FIG. 3 is a diagram explaining a state of a substrate mounting table and lifting pins according to the embodiments of the present disclosure.

FIG. 4A is a cross-sectional view (a cross-sectional view corresponding to FIG. 2A) of the mounting stage illustrating a state in which a film is formed on the substrate.

FIG. 4B is an enlarged view of a portion indicated by the arrow 4B in FIG. 4A.

FIG. 4C is an enlarged view of a portion indicated by the arrow 4C in FIG. 4B.

FIG. 4D is a cross-sectional view (a cross-sectional view corresponding to FIG. 4C) illustrating a state in which a second film has been made discontinuous.

FIG. 5A is a cross-sectional view (a cross-sectional view corresponding to FIG. 4B) of the mounting stage for explaining a thermal deformation amount of a first film and a thermal deformation amount of the second film.

FIG. 5B is a cross-sectional view (a cross-sectional view corresponding to FIG. 5A) of the mounting stage for explaining a state in which a discontinuous portion is formed in the second film.

FIG. 6A is a cross-sectional view (a cross-sectional view corresponding to FIG. 4B) of the mounting stage for explaining a thermal deformation amount of the first film and a thermal deformation amount of the second film.

FIG. 6B is a cross-sectional view (a cross-sectional view corresponding to FIG. 6A) of the mounting stage for explaining a state in which a discontinuous portion is formed in the second film.

FIG. 7A is a cross-sectional view (a cross-sectional view corresponding to FIG. 4B) of the mounting stage for explaining a thermal deformation amount of the first film and a thermal deformation amount of the second film.

FIG. 7B is a cross-sectional view (a cross-sectional view corresponding to FIG. 7A) of the mounting stage for explaining a state in which a discontinuous portion is formed in the second film.

FIG. 8A is a cross-sectional view (a cross-sectional view corresponding to FIG. 4B) of the mounting stage for explaining a thermal deformation amount of the first film and a thermal deformation amount of the second film.

FIG. 8B is a cross-sectional view (a cross-sectional view corresponding to FIG. 8A) of the mounting stage for explaining a state in which a discontinuous portion is formed in the second film.

FIG. 9 is a cross-sectional view (a cross-sectional view corresponding to FIG. 2A) of a mounting stage according to a modified example.

FIG. 10 is a cross-sectional view (a cross-sectional view corresponding to FIG. 4A) of a mounting stage according to a modified example.

FIG. 11 is a plan view (a plan view corresponding to FIG. 2B) of a mounting stage according to a modified example.

### DETAILED DESCRIPTION

A description will hereinafter be given of some embodiments of the present disclosure with consultation of the drawings.

Note that the drawings used in the following description are all schematic and thus, for example, the dimensional relationship between each constituent element and the ratio between each constituent element in the drawings do not necessarily coincide with realities. In addition, the dimensional relationship between each constituent element, the ratio between each constituent element, and the like do not necessarily coincide among a plurality of drawings.

### (1) Outline of Substrate Processing Apparatus

A substrate processing apparatus to be described in one or more embodiments is used in a semiconductor device manufacturing step and is configured to subject a substrate as an object to be processed to a process by heating the substrate with a heater or the like with the substrate placed in a process chamber. A non-limiting example of the substrate to be processed by the substrate processing apparatus may be a semiconductor wafer substrate on which a semiconductor device is fabricated. Examples of the semiconductor wafer substrate include a silicon (Si) substrate and a silicon carbide (SiC) substrate. Examples of the process performed by the substrate processing apparatus include a film formation process by thermal chemical vapor deposition (CVD) reaction.

### (2) Schematic Configuration of Substrate Processing Apparatus

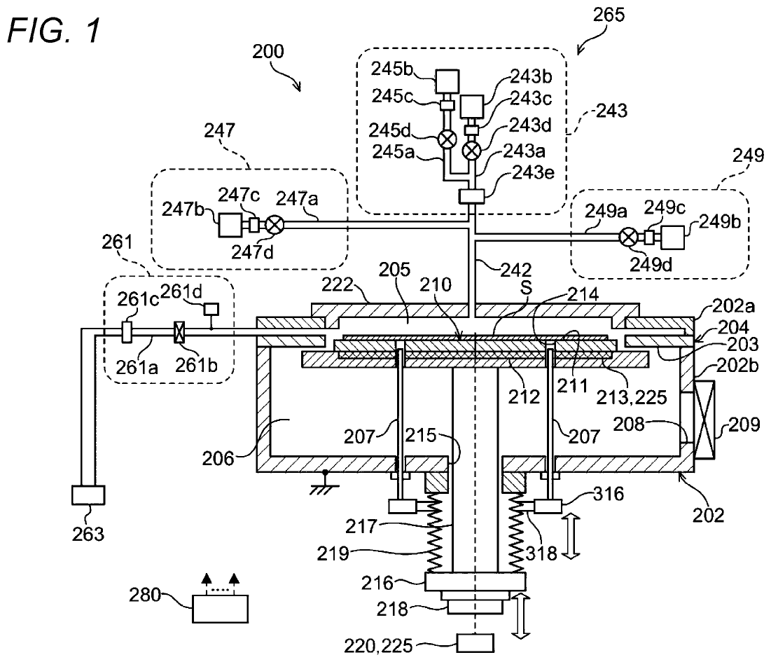

Next, a description will be given of an exemplary schematic configuration of a substrate processing apparatus to be suitably used in one or more embodiments of the present disclosure, with reference to FIG. 1. FIG. 1 is a longitudinal sectional view of a substrate processing apparatus to be suitably used in one or more embodiments of the present disclosure.

### (Overview of Apparatus)

A substrate processing apparatus 200 has a chamber 202. The chamber 202 is configured as, for example, a hermetically sealed flat container having a circular transverse cross section. The chamber 202 is made of, for example, a metal material such as aluminum (Al) or stainless steel (SUS).

The chamber 202 includes a process chamber 205 and a transfer chamber 206. The process chamber 205 is a room for processing a substrate S such as a silicon substrate serving as the substrate. The transfer chamber 206 is a room through which the substrate S passes when the substrate S is transferred to the process chamber 205.

The chamber 202 is constituted by an upper container 202a and a lower container 202b. A partition 204 is provided between the upper container 202a and the lower container 202b. The process chamber 205 is formed in an upper portion of the chamber 202, for example, on an upper side of a lower surface 203 of the partition 204. The process chamber 205 is mainly constituted by the upper container 202a, the partition 204, and a substrate mounting table 210 (details will be described later) that has moved to a processing position. The transfer chamber 206 is formed in a lower portion of the chamber 202, for example, on a lower side of the lower surface 203 of the partition 204. The transfer chamber 206 is mainly constituted by the lower container 202b, the partition 204, and the substrate mounting table 210 that has moved to a transfer position.

A substrate loading/unloading port 208 adjacent to a gate valve 209 is provided on a side surface of the lower container 202b. The substrate S moves between the lower container 202b and a vacuum transfer chamber (not illustrated) via the substrate loading/unloading port 208.

At a bottom wall of the lower container 202b, a plurality of lifting pins 207 is provided. The lower container 202b is grounded.

The substrate mounting table 210 is a constituent member on which the substrate S is mounted and the mounted substrate S is heated. The substrate mounting table 210 is an example of a mounting stage according to the present disclosure. The substrate mounting table 210 mainly includes a substrate mounting surface 211 and a heater 213.

The substrate mounting surface 211 is provided on a surface (an upper surface in FIG. 1) of the substrate mounting table 210 and is a portion on which the substrate S is mounted. In the present embodiments, the entire surface of the substrate mounting table 210 is assumed to be the substrate mounting surface 211, but the present disclosure is not limited to this.

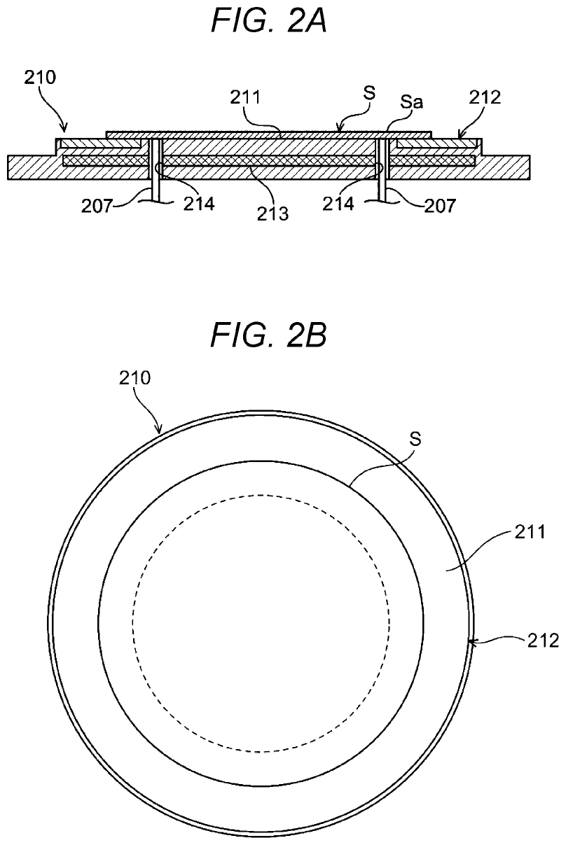

At least a part of the substrate mounting surface 211 is constituted by a first member 212. In the present embodiments, as illustrated in FIGS. 2A and 2B, a part of the substrate mounting surface 211 is constituted by the first member 212, but the present disclosure is not limited to this. For example, the entire substrate mounting surface 211 may be constituted by the first member 212.

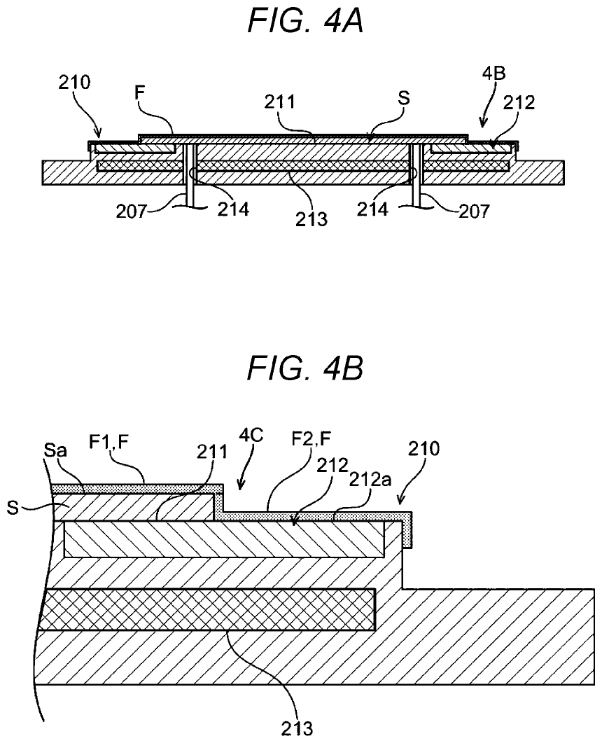

In the present embodiments, when the substrate S is mounted on the substrate mounting surface 211, the first member 212 comes into contact with the substrate S. Specifically, the first member 212 comes into contact with an outer peripheral edge Se (see FIG. 4C) of the substrate S. The outer peripheral edge Se illustrated in FIG. 4C indicates an edge of the outer peripheral edge Se of the substrate S on a side of the substrate mounting surface 211. In other words, in the present embodiments, the position of the first member 212 with respect to the substrate mounting surface 211 is set such that the first member 212 comes into contact with the outer peripheral edge Se of the substrate S when the substrate S is mounted on the substrate mounting surface 211. Furthermore, in the present embodiments, the position of the first member 212 with respect to the substrate mounting surface 211 is set such that the direction of thermal deformation of the first member 212 has a component oriented opposite to the direction of thermal deformation of the substrate S at the portion where the substrate S and the first member 212 are in contact. Specifically, the position of the first member 212 is set such that the substrate S is thermally deformed toward the center of the substrate S, and the first member 212 is thermally deformed in an orientation opposite to the direction toward the center of the substrate S. As an example, in the present embodiments, in a cross section of the first member 212, the position of the first member 212 is determined such that the outer peripheral edge Se of the mounted substrate S is positioned on an inner peripheral side of the center of the first member 212 in a width direction, as illustrated in FIG. 4B. Therefore, in a cross section of the first member 212, the inner peripheral side of the center of the first member 212 in the width direction is thermally deformed (thermally shrinks) in an orientation opposite to the direction toward the center of the substrate S. Specifically, in a cross section of the first member 212, the portion on the inner peripheral side and the portion on an outer peripheral side thermally shrink toward the center in the width direction.

As illustrated in FIG. 2A, an annular recess is provided in an upper portion of the substrate mounting table 210, and the annular plate-like first member 212 is fitted into the recess. The first member 212 is formed of a material different from the material of the substrate mounting table 210. Specifically, the substrate mounting table 210 and the first member 212 are formed of separate materials that give different thermal deformation amounts (materials having different thermal expansion coefficients). The thermal deformation amount mentioned here is an expression including a deformation amount due to thermal expansion and a deformation amount due to thermal shrinkage.

As illustrated in FIG. 2B, the first member 212 of the present embodiments is an integrally molded constituent member, but the present disclosure is not limited to this. For example, the first member 212 may be constituted by a plurality of constituent members formed of the same material. The first member 212 may be constituted by a plurality of constituent members formed of different materials or may be a constituent member obtained by integrally molding different materials.

The heater 213 is included in the substrate mounting table 210. The heater 213 has a function of heating the substrate S through the substrate mounting table 210. The heater 213 is an example of a heater of the present disclosure. The heater 213 is connected to a temperature controller 220 that controls a temperature of the heater 213. The substrate S is heated by heat from the heater 213. A temperature adjusting mechanism 225 is mainly constituted by the heater 213 and the temperature controller 220. The temperature adjusting mechanism 225 can change the temperature of at least one of the substrate S and the substrate mounting table 210. In the present embodiments, the substrate mounting table 210 is heated by heat from the heater 213. Then, the substrate S mounted on the heated substrate mounting surface 211 of the substrate mounting table 210 is heated.

In the substrate mounting table 210, through-holes 214 through which the lifting pins 207 pass are provided at positions in one-to-one correspondence with the lifting pins 207.

The substrate mounting table 210 is supported by a shaft 217. A lower end of the shaft 217 passes through a through-hole 215 provided in the bottom wall of the lower container 202b. A support plate 216 is provided at a lower end of the shaft 217. The shaft 217 is connected to an elevating mechanism 218 on an outer side of the chamber 202 (the lower side in FIG. 1) via the support plate 216. Therefore, the substrate S mounted on the substrate mounting surface 211 is elevated and lowered by operating the elevating mechanism 218 to elevate and lower the shaft 217 and the substrate mounting table 210. A circumference of a lower end of the shaft 217 is covered with a bellows 219. This holds the interior of the chamber 202 airtight.

At the time of processing the substrates S, the substrate mounting table 210 is elevated to the processing position where the substrate S is disposed in the process chamber 205 as illustrated in FIG. 1. While the substrate mounting table 210 is located at the processing position, the substrate S is positioned on an upper side of the lower surface 203 of the partition 204. At the time of transferring the substrate S, the substrate mounting table 210 is lowered to the transfer position where the substrate S is disposed in the transfer chamber 206 and the substrate mounting surface 211 faces the substrate loading/unloading port 208.

The lifting pins 207 are connected to an elevating mechanism 318 outside the chamber 202 via the support plate 316. The lifting pins 207 are elevated and lowered by operating the elevating mechanism 318. By operating the elevating mechanism 318 to cause distal ends of the lifting pins 207 to protrude from an upper surface of the substrate mounting surface 211, the substrate S can be supported from below by the distal ends of the lifting pins 207. By operating the elevating mechanism 318 to cause the distal ends of the lifting pins 207 to retract into the through-holes 214, the through-holes 214 can be closed with the distal ends of the lifting pins 207.

The upper container 202a includes a shower head 222 on a lid. A gas supplier to be described later is connected to the shower head 222. Specifically, a common gas supply pipe 242 is connected to the shower head 222, and each gas supplied into the shower head 222 is supplied to the process chamber 205.

### (Gas Supplier)

Subsequently, a description will be given of the gas supplier. A first gas supply pipe 243a, a second gas supply pipe 247a, and a third gas supply pipe 249a are connected to the common gas supply pipe 242.

### (First Gas Supply System)

A first processing gas is mainly supplied from a first gas supply system 243 including the first gas supply pipe 243a. A first gas supply source 243b, a mass flow controller (MFC) 243c as a flow rate controller, and a valve 243d as an on-off valve are provided upstream of the first gas supply pipe 243a in this order from an upstream direction. In order to bring the first processing gas into a plasma state, a remote plasma unit (RPU) 243e serving as a plasma generator is provided downstream of the valve 243d.

A first gas is supplied from the first gas supply pipe 243a into the shower head 222 via the MFC 243c, the valve 243d, and the common gas supply pipe 242. The first processing gas is brought into a plasma state by the RPU 243e.

The first processing gas is one of processing gases and is an oxygen-containing gas. As the oxygen-containing gas, for example, an oxygen (O₂) gas is used.

The first gas supply system 243 is mainly constituted by the first gas supply pipe 243a, the MFC 243c, the valve 243d, and the RPU 243e. The first gas supply system 243 may include a second gas supply source 247b and a hydrogen-containing gas supply system to be described later.

A downstream end of a hydrogen-containing gas supply pipe 245a is connected to a downstream side of the valve 243d of the first gas supply pipe 243a. The hydrogen-containing gas supply pipe 245a is provided with a hydrogen-containing gas supply source 245b, an MFC 245c as a flow rate controller, and a valve 245d as an on-off valve in this order from an upstream direction. A hydrogen-containing gas is supplied from the hydrogen-containing gas supply pipe 245a into the shower head 222 via the MFC 245c, the valve 245d, the first gas supply pipe 243a, and the RPU 243e.

As the hydrogen-containing gas, for example, a hydrogen (H₂) gas or a water (H₂O) gas can be used. The hydrogen-containing gas supply system is mainly constituted by the hydrogen-containing gas supply pipe 245a, the MFC 245c, and the valve 245d. The hydrogen-containing gas supply system may be supposed to include the hydrogen-containing gas supply source 245b, the first gas supply pipe 243a, and the RPU 243e. The hydrogen-containing gas supply system may be included in the first gas supply system 243.

### (Second Gas Supply System)

A second processing gas is mainly supplied from a second gas supply system 247 including the second gas supply pipe 247a. The second gas supply pipe 247a is provided with a second gas supply source 247b, an MFC 247c as a flow rate controller, and a valve 247d as an on-off valve in this order from an upstream direction.

A gas containing a second element (hereinafter, referred to as a “second processing gas”) is supplied to the shower head 222 from the second gas supply pipe 247a via the MFC 247c, the valve 247d, and the common gas supply pipe 242.

The second processing gas is, for example, a processing gas containing silicon (Si). That is, the second processing gas is, for example, a silicon-containing gas. As the silicon-containing gas, for example, a silane-based gas such as a monosilane (SiH₄) gas, a disilane (Si₂H₆) gas, or a trisilane (Si₃H₈) gas is used. As a silicon-containing gas containing impurities such as a carbon component and a boron component, for example, tetraethyl orthosilicate (Si(OC₂H₅)₄; also referred to as TEOS) gas or the like is used. The aforementioned first processing gas and the second processing gas are examples of a first gas of the present disclosure.

The second gas supply system 247 (also referred to as a silicon-containing gas supply system) is mainly constituted by the second gas supply pipe 247a, the MFC 247c, and the valve 247d.

### (Third Gas Supply System)

An inert gas is mainly supplied from a third gas supply system 249 including the third gas supply pipe 249a. The third gas supply pipe 249a is provided with a third gas source 249b, an MFC 249c as a flow rate controller, and a valve 249d as an on-off valve in this order from an upstream direction. The third gas source 249b is an inert gas source. The inert gas is, for example, a nitrogen (N₂) gas. The inert gas is an example of a second gas of the present disclosure. The inert gas has higher thermal conductivity than the thermal conductivity of the first processing gas and the second processing gas.

The third gas supply system 249 is mainly constituted by the third gas supply pipe 249a, the MFC 249c, and the valve 249d.

The inert gas supplied from the third gas source 249b is used as a purge gas for purging the gas remaining in the chamber 202 and the shower head 222 in a substrate processing step.

### (Exhauster)

An exhauster that exhausts an atmosphere in the chamber 202 is mainly constituted by an exhauster 261 configured to exhaust an atmosphere in the process chamber 205.

The exhauster 261 includes an exhaust pipe 261a connected to the process chamber 205. The exhaust pipe 261a is provided so as to communicate with the process chamber 205. The exhaust pipe 261a is provided with an auto pressure controller (APC) 261c as a pressure controller for controlling the interior of the process chamber 205 to a predetermined pressure, and a pressure detector 261d that measures the pressure in the process chamber 205. The APC 261c includes a valve body (not illustrated) having a regulatable opening degree and regulates a conductance of the exhaust pipe 261a in accordance with an instruction from a controller 280 (to be described later). A valve 261b is provided in the exhaust pipe 261a on an upstream side of the APC 261c. The exhaust pipe 261a, the valve 261b, the APC 261c, and the pressure detector 261d are collectively referred to as the exhauster 261.

A dry pump 263 is provided on a downstream side of the exhaust pipe 261a. The dry pump 263 exhausts an atmosphere in the process chamber 205 via the exhaust pipe 261a.

A film forming mechanism 265 is mainly constituted by the first gas supply system 243, the second gas supply system 247, and the third gas supply system 249. The film forming mechanism 265 may include the exhauster 261.

### (Controller)

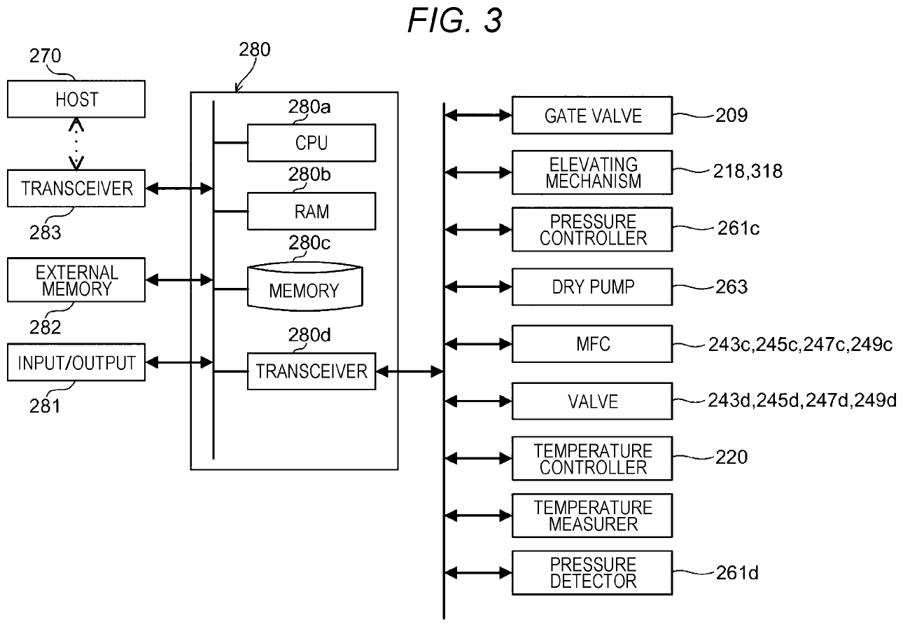

Next, the controller 280 that controls the operation of each constituent of the substrate processing apparatus 200 will be described with reference to FIG. 3. The controller 280 is an example of a controller of the present disclosure. FIG. 3 is a diagram explaining the controller 280 of the substrate processing apparatus 200.

The substrate processing apparatus 200 includes the controller 280 that controls the operation of each constituent of the substrate processing apparatus 200. As illustrated in FIG. 3, the controller 280 includes at least a calculator (central processing unit (CPU)) 280a, a transitory memory 280b, a memory 280c, and a transceiver 280d. The controller 280 is connected to each constituent of the substrate processing apparatus 200 via the transceiver 280d, calls out a program or a recipe from the memory 280c in accordance with an instruction from a host controller or a user, and controls the operation of each constituent in accordance with the contents of the instruction. Each constituent of the substrate processing apparatus 200 includes the elevating mechanism 218 and the elevating mechanism 318. The controller 280 is configured such that the controller 280 can control the operations of the elevating mechanism 218 and the elevating mechanism 318 by executing a program in which a procedure for carrying out each step in the substrate processing step is described.

The controller 280 may be configured as a special-purpose computer or a general-purpose computer. For example, the controller 280 according to the present embodiments can be configured in such a manner that an external memory (e.g., a magnetic tape; a magnetic disk such as a flexible disk or a hard disk; an optical disc such as a compact disc (CD) or a digital versatile disc (DVD); a magneto-optical disk such as an MO; a semiconductor memory such as a universal serial bus (USB) memory (a USB flash drive) or a memory card) 282 that stores the foregoing program is prepared, and then the program is installed in a general-purpose computer, using the external memory 282. As for a supplier of the program to the computer, the program does not have to be supplied to the computer via the external memory 282. For example, communication tools such as the internet or a dedicated line may be used, or information may be received from a host 270 via a transceiver 283 such that the program is supplied not via the external memory 282. Instructions may be given to the controller 280, using an input/output 281 such as a keyboard or a touch panel.

Each of the memory 280c and the external memory 282 is configured as a computer-readable recording medium. These memories will hereinafter also be collectively referred to simply as a recording medium. Note that, in the present specification, the term “recording medium” may include only the memory 280c alone, only the external memory 282 alone, or both of them.

### (Substrate Processing Step)

Next, one step of a semiconductor manufacturing step will be described. Here, a film forming step of forming a carbon-containing SiO₂ film on a Si substrate S will be described.

### (Substrate Loading Step)

In the substrate processing apparatus 200 in FIG. 1, the gate valve 209 is opened, and the substrate S is loaded into the lower container 202b of the chamber 202, that is, into the transfer chamber 206 from the substrate loading/unloading port 208. The substrate S is mounted on distal ends of the plurality of lifting pins 207 protruding from the substrate mounting surface 211. The gate valve 209 is then closed. Thereafter, the substrate mounting table 210 is elevated, and the substrate S is mounted on the substrate mounting surface 211. Then, the substrate mounting table 210 stops at the processing position. Next, the plurality of lifting pins 207 move to positions where the lifting pins 207 do not touch the substrate S in the through-holes 214. When the substrate S is mounted on the substrate mounting surface 211, the first member 212 comes into contact with the substrate S. Specifically, the first member 212 comes into contact with the outer peripheral edge Se (see FIG. 4C) of the substrate S.

### (Film Forming Step)

After the substrate S is heated to a predetermined temperature while the substrate S is located in the process chamber 205, the silicon-containing gas and the oxygen-containing gas are supplied to the process chamber. The silicon-containing gas contains impurities such as a carbon component and a boron component. As the silicon-containing gas, for example, a TEOS gas is used. As the oxygen-containing gas, for example, an oxygen (O₂) gas is used.

The TEOS gas and the O₂ gas supplied to the process chamber react with each other, and a film F is formed on the substrate S. Specifically, as illustrated in FIG. 4A, the film F is formed on a surface Sa of the substrate S and the substrate mounting surface 211 around the surface Sa. In the film F, a film formed on the surface Sa of the substrate S will be referred to as a first film F1. In the film F, a film formed on the substrate mounting surface 211 around the surface Sa of the substrate S will be referred to as a second film F2. In the present embodiments, a part of the substrate mounting surface 211 is formed of the first member 212. Therefore, the second film F2 is formed on a surface 212a of the first member 212. The second film F2 has a portion continuous with the first film F1. In the example illustrated in FIG. 4B, the portion of the second film F2 continuous with the first film F1 is a region formed along an outer peripheral surface of the substrate S.

The film F formed on the substrate S is a carbon-containing SiO₂ film containing silicon and a carbon component contained in the TEOS gas, and an oxygen component of the O₂ gas. As the silicon-containing gas, a gas containing a silicon component and a boron component may be used. In this case, a boron-containing SiO₂ film containing a boron component instead of the carbon component is formed. When a predetermined time has elapsed and a carbon-containing SiO₂ film having a desired thickness of film has been formed on the substrate S, the supply of each processing gas is stopped.

### (Cooling Step)

After the supply of each processing gas is stopped, the temperature of the substrate S and/or the first member 212 (the temperature in the process chamber 205) is made lower than the temperature in the film forming step. For example, the temperature in the process chamber 205 is decreased by making the output of the heater 213 smaller than the output in the film forming step or making the output zero. Alternatively, an inert gas may be supplied to the process chamber 205 from the third gas supply system 249 to reduce the temperature in the process chamber 205. That is, by reducing the temperature in the process chamber 205 with the supply of the inert gas, the temperatures of the substrate S and the first member 212 may be decreased.

When the temperature of each of the substrate S and the first member 212 decreases, as illustrated in FIG. 4C, stress attributable to a difference in thermal deformation amount between the first member 212 and the substrate S is generated inside the second film F2. For example, the stress attributable to a difference in thermal deformation amount between the first member 212 and the substrate S occurs by mainly concentrating on a bent portion of the second film F2. In FIG. 4C, the bent portion of the second film F2 is a boundary portion between a portion formed along the surface 212a of the first member 212 and a portion formed along the outer peripheral surface of the substrate S. In FIG. 4C, the boundary portion is indicated by the dotted line.

When the stress generated inside the second film F2 becomes a predetermined value or more, at least a part of the second film F2 becomes discontinuous in a portion around the substrate S. Specifically, as illustrated in FIG. 4D, a portion of the second film F2 where the stress is concentrated is broken. The broken portion is formed at one or a plurality of places in the portion of the second film F2 around the substrate S. That is, the cooling step of the present embodiments is an example of a step of generating stress attributable to a difference in thermal deformation amount between the first member 212 and the substrate S, inside the second film F2, and making at least a part of the second film F2 around the substrate S discontinuous.

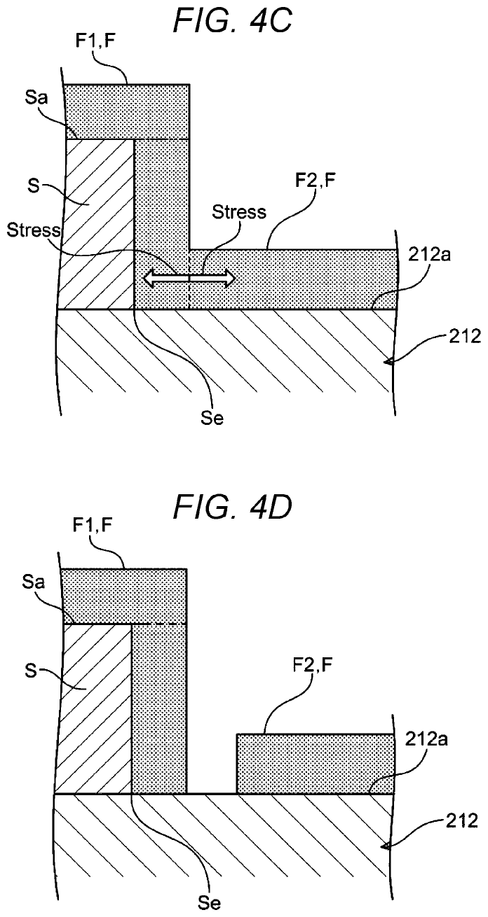

Here, patterns when a discontinuous portion is formed in the second film F2 will be described with reference to FIGS. 5A, 5B, 6A, 6B, 7A, 7B, 8A, and 8B. Here, the arrows illustrated in these drawings each schematically indicate the orientation and the size of the thermal deformation amount of the substrate S or the first member 212. Since only one side of the substrate S is illustrated for the arrows illustrated in these drawings, the arrows indicating the thermal deformation amount of the substrate S are illustrated only on one side.

The example illustrated in FIG. 5A illustrates a pattern in which the thermal expansion coefficient of the first member 212 is smaller than the thermal expansion coefficient of the substrate S. In the pattern in FIG. 5A, since the thermal deformation amount of the first member 212 is smaller than the thermal deformation amount of the substrate S, in the case of the pattern in FIG. 5A with a smaller thermal deformation amount of the first member 212 than the thermal deformation amount of the substrate S in which the arrow indicating the thermal deformation amount of the first member 212 is shorter than the arrow indicating the thermal deformation amount of the substrate S, tensile stress concentrates on the boundary portion of the second film F2, and the second film F2 breaks and becomes discontinuous, as illustrated in FIG. 5B.

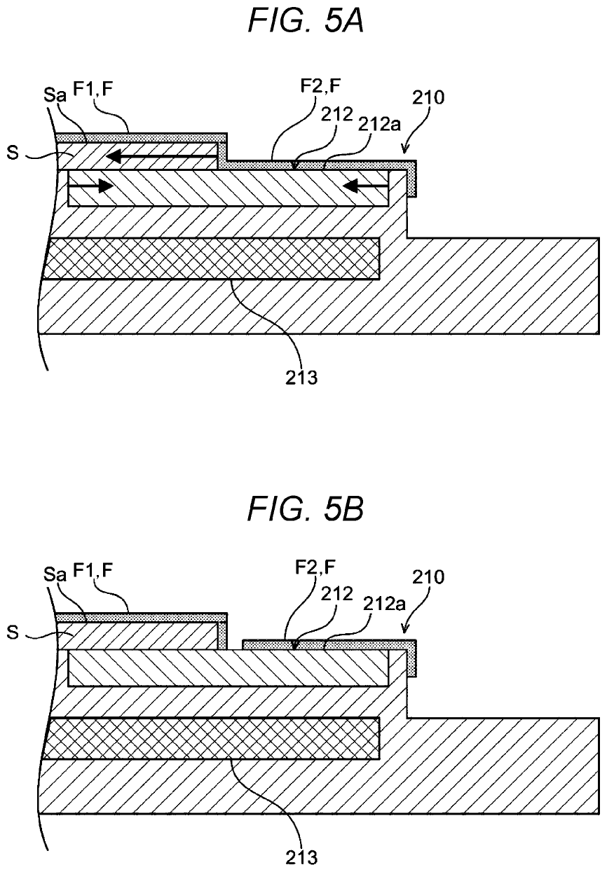

The example illustrated in FIG. 6A illustrates a pattern in which the thermal expansion coefficient of the first member 212 is larger than the thermal expansion coefficient of the substrate S. In the pattern in FIG. 6A, since the thermal deformation amount of the first member 212 is larger than the thermal deformation amount of the substrate S, the arrow indicating the thermal deformation amount of the first member 212 is longer than the arrow indicating the thermal deformation amount of the substrate S. In the case of the pattern in FIG. 6A in which the thermal deformation amount of the first member 212 is larger than the thermal deformation amount of the substrate S, tensile stress concentrates on the boundary portion of the second film F2, and the second film F2 breaks and becomes discontinuous, as illustrated in FIG. 6B. The tensile stress also concentrates on the second film F2 in the vicinity of an outer peripheral edge of the substrate mounting surface 211, and the second film F2 breaks and becomes discontinuous.

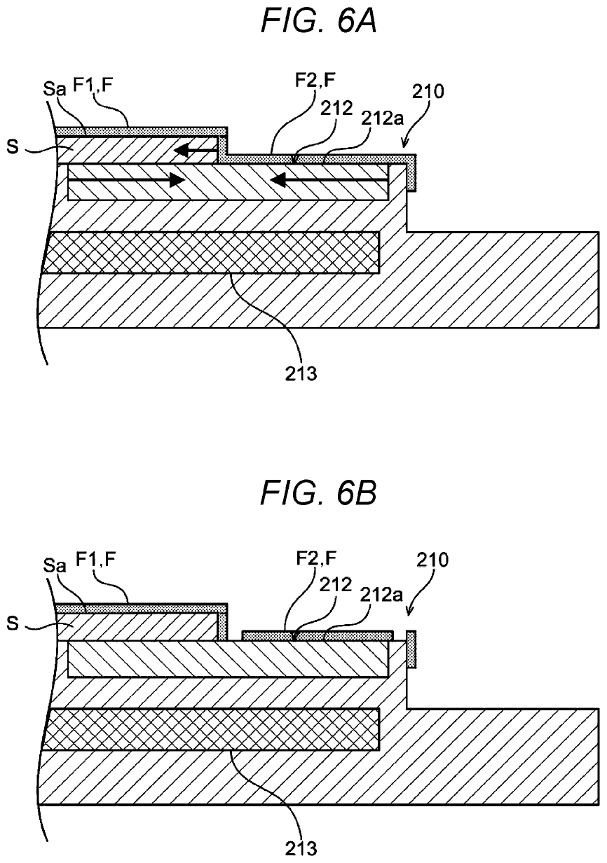

The example illustrated in FIG. 7A is an example in which the entire substrate mounting surface 211 is formed by the first member 212 and illustrates a pattern in which the thermal expansion coefficient of the first member 212 is smaller than the thermal expansion coefficient of the substrate S. In the pattern in FIG. 7A, since the thermal deformation amount of the first member 212 is smaller than the thermal deformation amount of the substrate S, the arrow indicating the thermal deformation amount of the first member 212 is shorter than the arrow indicating the thermal deformation amount of the substrate S. In the case of the pattern in FIG. 7A in which the thermal deformation amount of the first member 212 is smaller than the thermal deformation amount of the substrate S, tensile stress concentrates on the boundary portion of the second film F2, and the second film F2 breaks and becomes discontinuous, as illustrated in FIG. 7B. That is, in the example in FIG. 7A, the same region as in the example in FIG. 5A is broken.

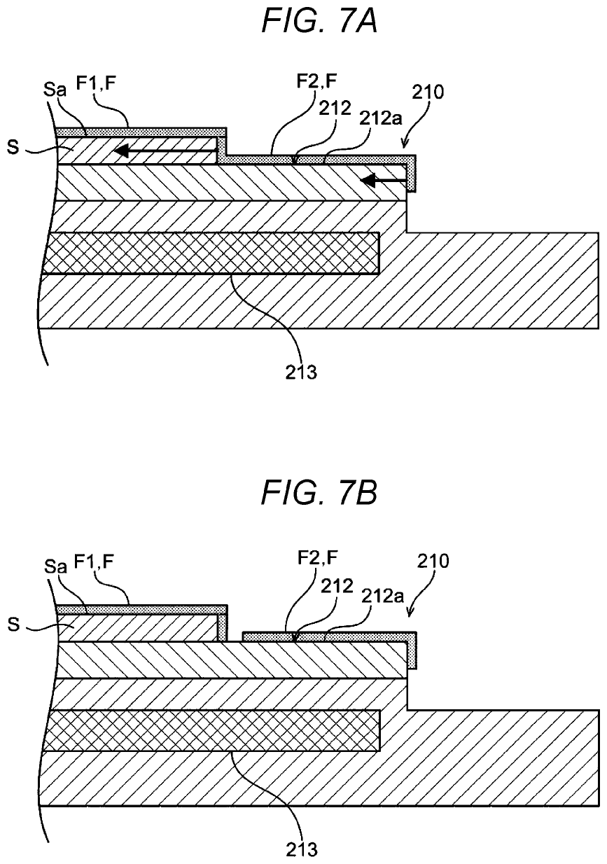

The example illustrated in FIG. 8A is an example in which the entire substrate mounting surface 211 is formed by the first member 212 and illustrates a pattern in which the thermal expansion coefficient of the first member 212 is larger than the thermal expansion coefficient of the substrate S. In the pattern in FIG. 8A, since the thermal deformation amount of the first member 212 is larger than the thermal deformation amount of the substrate S, the arrow indicating the thermal deformation amount of the first member 212 is longer than the arrow indicating the thermal deformation amount of the substrate S. In the case of the pattern in FIG. 8A in which the thermal deformation amount of the first member 212 is larger than the thermal deformation amount of the substrate S, the second film F2 breaks and becomes discontinuous at the boundary portion of the second film F2, as illustrated in FIG. 8B. In the case of the example in FIG. 5A, the example in FIG. 6A, and the example in FIG. 7A, the second film F2 is broken by the tensile stress occurring at the boundary portion of the second film F2, but in the case of the example in FIG. 8A, the second film F2 is broken by shear stress occurring at the boundary portion of the second film F2.

When the thermal expansion coefficient of the first member 212 is made smaller than the thermal expansion coefficient of the substrate S, for example, a material having a covalent bond can be used as the material of the first member 212. As the material having a covalent bond, for example, a ceramic material such as silicon oxide, silicon carbide, aluminum nitride, aluminum oxide, zirconium oxide, yttrium oxide, or silicon nitride can be used.

When the thermal expansion coefficient of the first member 212 is made larger than the thermal expansion coefficient of the substrate S, for example, a metal material or a polymer material can be used as the material of the first member 212. As the metal material, for example, aluminum, iron, titanium, niobium, molybdenum, tantalum, tungsten, rhenium, an alloy obtained by adding another element thereto, and the like can be used. As the polymer material, polystyrene, polycarbonate, polyimide, or the like can be used.

Among the above-mentioned materials, a material having a large difference from the thermal expansion coefficient of the substrate S is preferably used as the material of the first member 212. Among the above-mentioned materials, a material that is thermally and chemically stable during the substrate processing step is preferably used as the material of the first member 212.

### (Substrate Unloading Step)

When the cooling of the substrate S is completed, the substrate mounting table 210 is lowered to the transfer position. At this time, the substrate S is mounted on the distal ends of the plurality of lifting pins 207 protruding from the surface of the substrate mounting table 210. Next, the gate valve 209 of the substrate processing apparatus 200 is opened, and the substrate S in the chamber 202 is unloaded to the outside of the chamber 202 through the substrate loading/unloading port 208. The gate valve 209 is then closed, and the substrate processing step ends. The substrate S thus unloaded is transferred to the subsequent processing step.

Next, effects of the present embodiments will be described. In the present embodiments, in the cooling step, stress attributable to a difference in thermal deformation amount between the first member 212 and the substrate S is generated inside the second film F2, and at least a part of the second film F2 at a portion around the substrate S is made discontinuous, as illustrated in FIG. 4C. That is, as illustrated in FIG. 4D, the portion where the stress concentrates in the second film F2 is broken, whereby a discontinuous portion is formed in the second film F2. This enables to suppress transfer failure due to positional deviation when the substrate S is transferred from the substrate mounting table 210 and damage to the substrate S when the substrate S is lifted from the substrate mounting surface 211, which are caused by continuation of the first film F1 and the second film F2.

In the present embodiments, the first member 212 is in contact with the substrate S while the substrate S is mounted on the substrate mounting surface 211. This ensures to suppress discontinuity of the second film F2 at a position away from the outer peripheral edge Se of the substrate S as compared with a case where the first member 212 is not brought into contact with the substrate S. Accordingly, a part of the second film F2 adhering to the outer peripheral edge Se of the substrate S can be avoided from being peeled off and becoming particles during transfer or the like of the substrate S.

In the present embodiments, the first member 212 is in contact with the outer peripheral edge Se of the substrate S while the substrate S is mounted on the substrate mounting surface 211. This facilitates to form a portion where stress is concentrated in the second film F2 as illustrated in FIG. 4D, and thus a continuous portion between the surface Sa of the substrate S and the surface 212a of the first member 212 is easily made into a discontinuous portion.

In the present embodiments, by supplying the second gas into the process chamber 205 in the cooling step, the temperature of at least one of the substrate S and the first member 212 is decreased in a shorter time to form a discontinuous portion in the second film F2. This promotes thermal deformation in the first member 212 and the substrate S by supplying the second gas, and thus the time taken to form the discontinuous portion in the second film F2 can be shortened.

In the present embodiments, an inert gas is used as the second gas in the cooling step. By supplying the inert gas to the second film F2 in this manner, the temperatures of the substrate S and the first member 212 can be decreased without altering the film.

In the present embodiments, a gas having a higher thermal conductivity than the first gas is used as the second gas in the cooling step. Therefore, the temperature of at least one of the substrate S and the first member 212 can be decreased in a shorter time, and the time taken to form the discontinuous portion in the second film F2 can be further shortened. Here, as the gas having a higher thermal conductivity than the first gas, for example, a gas having a smaller molecular weight of gas molecules per unit volume than the first gas can be used.

In the present embodiments, in the cooling step, the first member 212 is disposed with respect to the substrate mounting surface 211 such that the direction of thermal deformation of the first member 212 has a component orientated opposite to the direction of thermal deformation of the substrate S at the portion where the substrate S and the first member 212 are in contact. By disposing the first member 212 in this manner, stress attributable to a difference in thermal deformation amount between the first member 212 and the substrate S generated inside the second film F2 can be increased. This allows the time taken to form the discontinuous portion in the second film F2 to be further shortened.

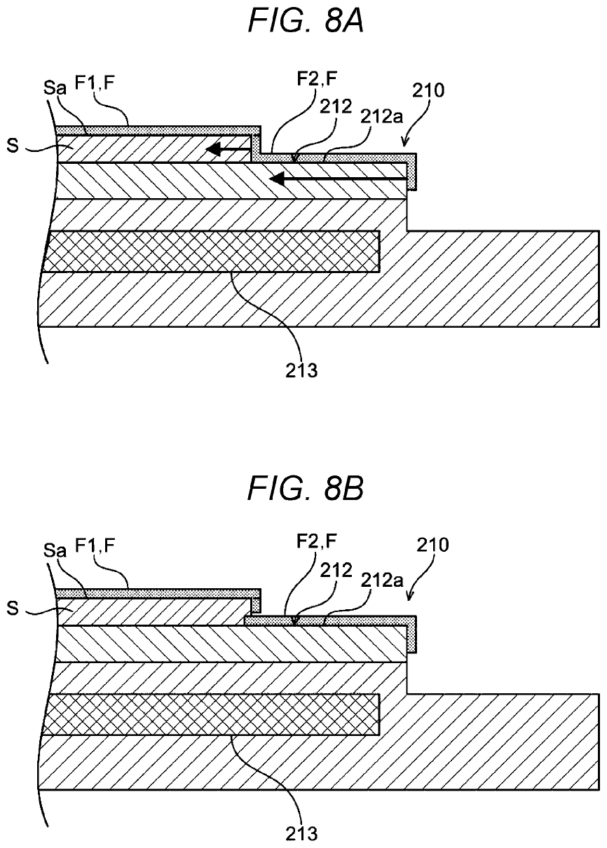

In the above-described embodiments, in the cooling step, the temperature in the process chamber 205 is reduced by the inert gas to form the discontinuous portion in the second film F2, but the present disclosure is not limited to this. For example, as in the example illustrated in FIG. 9, a substrate mounting table 410 may include flow paths 412 configured to allow a refrigerant to flow. In the cooling step, by supplying the refrigerant to these flow paths 412, the temperature of at least one of the substrate S and the first member 212 can be made lower than the temperature in the film forming step. Since the substrate mounting table 410 includes the flow paths 412 in this manner, thermal deformation of the first member 212 and the substrate S can be promoted. This allows the time taken to form the discontinuous portion in the second film F2 to be further shortened. In the substrate mounting table 410, the flow paths 412 are provided on lateral sides (that is, an outer periphery) of the heater 213. By providing the flow paths 412 on the lateral sides of the heater 213 in this manner, the heating of the substrate S can be restrained from being hindered by the flow paths 412. In the substrate mounting table 410, the first member 212 is disposed above the flow paths 412. By disposing the first member 212 above the flow paths 412 in this manner, thermal deformation of the first member 212 can be promoted while the heating of the substrate S is restrained from being hindered. The inert gas may be supplied to the process chamber 205 together with the refrigerant supplied to the flow paths 412. By cooling using the refrigerant and the inert gas, the discontinuous portion can be efficiently formed in the second film F2.

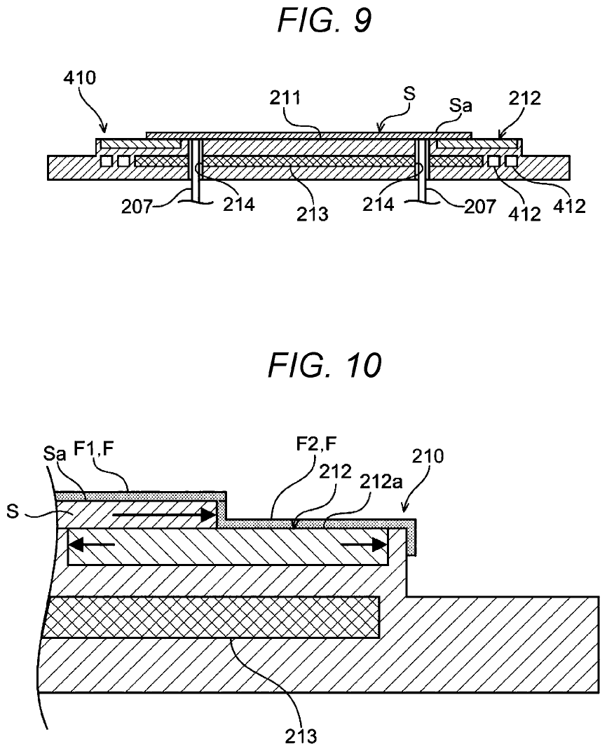

In the above-described embodiments, the discontinuous portion is formed in the second film F2 by cooling at least one of the substrate S and the first member 212 in the cooling step, but the present disclosure is not limited to this. For example, as in the example illustrated in FIG. 10, after the film F is formed on the surface Sa of the substrate S, the substrate mounting table 210 and the substrate S may be heated by the heater 213. In this case, the substrate S is thermally deformed in an orientation opposite to the direction toward the center of the substrate S, and the first member 212 is thermally deformed, for example, toward the center of the substrate S. Specifically, in a cross section of the first member 212, an inner peripheral side of the center in the width direction is thermally deformed (thermally expanded) toward the center of the substrate S. Also in this case, the discontinuous portion can be formed in the second film F2 similarly to the above-described embodiments.

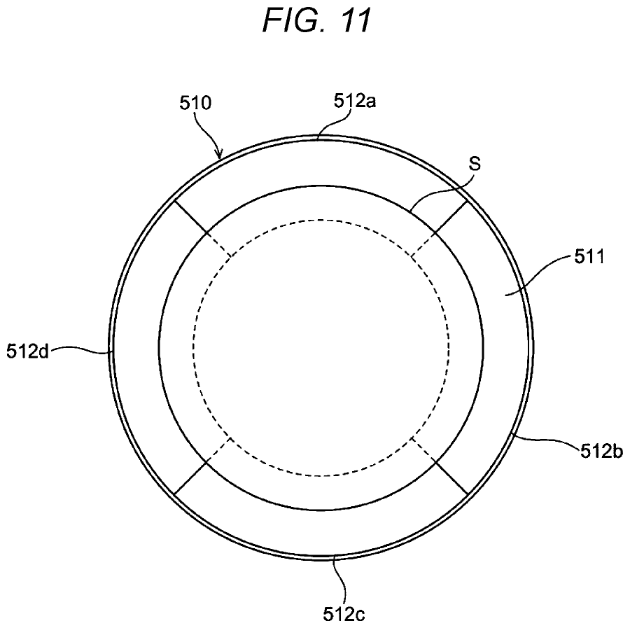

In the above-described embodiments, one first member 212 constitutes a part of the substrate mounting surface 211, but the present disclosure is not limited to this. For example, as in the example illustrated in FIG. 11, at least a part of a substrate mounting surface 511 of a substrate mounting table 510 may be constituted by a plurality of first members. Specifically, a part of the substrate mounting surface 511 may be constituted by four first members 512a, 512b, 512c, and 512d. By constituting at least a part of the substrate mounting surface 511 of the substrate mounting table 510 with the plurality of first members 512a, 512b, 512c, and 512d in this manner, stress attributable to a difference in thermal deformation amount between each first member and the substrate S generated inside the second film F2 can be increased. The plurality of first members may be thermally deformed independently of each other. Specifically, the thermal deformation amounts of the plurality of first members 512a, 512b, 512c, and 512d may be made different from each other. By thermally deforming the plurality of first members independently of each other in this manner, stress attributable to a difference in thermal deformation amount between each first member and the substrate S generated inside the second film F2 can be further increased. The plurality of first members may have a pair of first members configured such that a certain first member is located at a position facing another first member with the substrate S interposed therebetween. By disposing the pair of first members at facing positions with the substrate S interposed therebetween in this manner, stress attributable to a difference in thermal deformation amount between each first member and the substrate S generated inside the second film F2 can be further increased.

In the above-described embodiments, a carbon-containing SiO₂ film is formed on the substrate, but the present disclosure is not limited to this. For example, a film mainly constituted by a predetermined first element may be formed on the substrate. As the first element, for example, one or a plurality of kinds of: calcium (Ca) and strontium (Sr) as Group 2 elements; scandium (Sc), yttrium (Y), lanthanoids, and actinoids as Group 3 elements; titanium (Ti), zirconium (Zr), and hafnium (Hf) as Group 4 elements; vanadium (V), niobium (Nb), and tantalum (Ta) as Group 5 elements; chromium (Cr), molybdenum (Mo), and tungsten (W) as Group 6 elements; manganese (Mn), technetium (Tc), and rhenium (Re) as Group 7 elements; iron (Fe), ruthenium (Ru), and osmium (Os) as Group 8 elements; cobalt (Co), rhodium (Rh), and iridium (Ir) as Group 9 elements; nickel (Ni), palladium (Pd), and platinum (Pt) as Group 10 elements; copper (Cu), silver (Ag), and gold (Au) as Group 11 elements; zinc (Zn) as a Group 12 element; aluminum (Al), gallium (Ga), and indium (In) as Group 13 elements; carbon (C), Si, germanium (Ge) as Group 14 elements, and the like can be used.

For example, a film mainly constituted by the above-described first element and a predetermined second element may be formed on the substrate. As the second element, for example, one or a plurality of kinds of boron (B) as a Group 13 element, nitrogen (N), phosphorus (P), arsenic (As), and antimony (Sb) as Group 15 elements, oxygen (0), sulfur(S), and selenium (Se) as Group 16 elements, and the like can be used.

In the above-described embodiments, the first processing gas and the second processing gas are used as an example of the first gas, but the present disclosure is not limited to this. Only one of the first processing gas and the second processing gas may be used as the first gas. In the above-described embodiments, the carbon-containing SiO₂ film is formed on the substrate, using the oxygen-containing gas as an example of the first processing gas and the silicon-containing gas as an example of the second processing gas, but the present disclosure is not limited to this. As the first gas, for example, one or a plurality of a first element-containing gas that is a gas containing the above-described first element, a second element-containing gas that is a gas containing the above-described second element, and the like can be used.

The above-described embodiments have described an exemplary case where a film is formed using a single-wafer processing type substrate processing apparatus configured to process one or several substrates at a time. However, the present disclosure is not limited to the above-described embodiments. For example, the present disclosure is suitably applicable also to a case where a film is formed using a batch-type substrate processing apparatus configured to process a plurality of substrates at a time. For example, the mounting stage in the present disclosure may be a boat configured such that a plurality of substrates S, for example, two or more but 300 or less substrates S are allowed to be mounted, and at least a part of a surface of the boat may be constituted by the first member. The above-described embodiments have also described an exemplary case where a film is formed using a substrate processing apparatus including a cold wall-type process furnace. The present disclosure is not limited to the above-described embodiments and suitably applicable also to a case where a film is formed using a substrate processing apparatus including a hot wall-type process furnace. Also in cases where these substrate processing apparatuses are used, the respective processes can be performed by similar processing procedures and on similar processing conditions to those in the above-described embodiments, and similar outcomes to those in the above-described embodiments and modified examples can be produced.

While specific description has been given above based on the embodiments and modified examples, the present disclosure is not limited to the above-described embodiments and modified examples, and it goes without saying that various modifications can be made. The above-described embodiments and modified examples can be appropriately used in combination. Processing procedures and processing conditions at this time can be made similar to the processing procedures and processing conditions in the above-described embodiments and modified examples, for example.

According to the present disclosure, failure in transferring a substrate and damage to a substrate can be suppressed.

What is claimed is:

1. A method of processing a substrate, comprising:
(a) mounting the substrate on a mounting stage in which at least a part of a surface is constituted by a first member;
(b) forming films by supplying a first gas, the films including a first film formed on a surface of the substrate and a second film having a portion continuous with the first film and formed on a surface of the first member; and
(c) generating stress attributable to a difference in thermal deformation amount between the first member and the substrate, inside the second film, and making at least a part of the second film discontinuous.

2. The method according to claim 1, wherein the first member is in contact with the substrate.

3. The method according to claim 2, wherein the first member is in contact with an edge of the substrate.

4. The method according to claim 1, wherein (c), a temperature of at least one of the substrate and the first member is made lower than a temperature in the forming films, by supplying a second gas.

5. The method according to claim 4, wherein the second gas includes an inert gas.

6. The method according to claim 4, wherein the second gas has a higher thermal conductivity than the first gas.

7. The method according to claim 1, wherein the mounting stage further includes a flow path configured to allow a refrigerant to flow, and in (c), a temperature of at least one of the substrate and the first member is made lower than a temperature in the forming films, by supplying the refrigerant.

8. The method according to claim 7, wherein the mounting stage further includes a heater that heats the substrate, and the flow path is provided on a lateral side of the heater.

9. The method according to claim 8, wherein the first member is arranged above the flow path.

10. The method according to claim 1, wherein the first member is arranged such that a direction of thermal deformation of the first member has a component orientated opposite to a direction of thermal deformation of the substrate at a portion where the substrate and the first member are in contact.

11. The method according to claim 10, wherein in (c), the substrate is thermally deformed toward a center of the substrate, and the first member is thermally deformed in an orientation opposite to a direction toward the center of the substrate.

12. The method according to claim 10, wherein in (c), the substrate is thermally deformed in an orientation opposite to a direction toward a center of the substrate, and the first member is thermally deformed toward the center of the substrate.

13. The method according to claim 1, wherein the surface of the mounting stage is constituted by a plurality of the first members.

14. The method according to claim 13, wherein the plurality of the first members is thermally deformed independently of each other.

15. The method according to claim 13, wherein the plurality of the first members includes a pair of the first members configured such that a certain one of the first members is located at a position facing another one of the first members with the substrate interposed between the certain first member and the another first member.

16. The method according to claim 1, wherein the mounting stage is configured such that a plurality of the substrates is allowed to be mounted.

17. A method of manufacturing a semiconductor device, comprising the method of claim 1.

18. A substrate processing apparatus comprising:
a mounting stage in which at least a part of a surface is constituted by a first member;
a film forming mechanism configured to form films, the films including a first film formed on a surface of a substrate mounted on the mounting stage and a second film having a portion continuous with the first film and formed on a surface of the first member;
a temperature adjusting mechanism configured to change a temperature of at least one of the substrate and the mounting stage; and
a controller configured to be capable of controlling the film forming mechanism and the temperature adjusting mechanism so as to perform a process including: (a) mounting the substrate on the mounting stage; (b) forming films, the films including a first film formed on a surface of the substrate and a second film having a portion continuous with the first film and formed on a surface of the first member; and (c) generating stress attributable to a difference in thermal deformation amount between the first member and the substrate, inside the second film, and making at least a part of the second film discontinuous.

19. A non-transitory computer-readable recording medium storing a program that causes, by a computer, a substrate processing apparatus to perform:
(a) mounting a substrate on a mounting stage in which at least a part of a surface is constituted by a first member;
(b) forming films by supplying a first gas, the films including a first film formed on a surface of the substrate and a second film having a portion continuous with the first film and formed on a surface of the first member; and
(c) generating stress attributable to a difference in thermal deformation amount between the first member and the substrate, inside the second film, and making at least a part of the second film discontinuous.
